(19) United States
(12) Patent Application Publication
(10) Pub. No.: US 2010/0130017 A1
(43) Pub. Date: May 27, 2010

(54) FRONT END OF LINE PLASMA MEDIATED ASHING PROCESSES AND APPARATUS

(75) Inventors: Shijian Luo, South Hamilton, MA (US); Orlando Escorcia, Falls Church, VA (US); Carlo Waldfried, Falls Church, VA (US); Ivan Berry, Ellicott City, MD (US)

Correspondence Address: CANTOR COLBURN, LLP, 20 Church Street, 22nd Floor, Hartford, CT, 06103, US

(73) Assignee: AXCELIS TECHNOLOGIES, INC., Beverly, MA (US)

(21) Appl. No.: 12/275,394

(22) Filed: Nov. 21, 2008

(51) Int. Cl. H01L 21/3065

(52) U.S. Cl. 438/710; 156/345.35; 257/E21.218

(57) ABSTRACT

Front end of line (FEOL) plasma mediated ashing processes for removing organic material from a substrate generally includes exposing the substrate to the plasma to selectively remove photoresist, implanted photoresist, polymers and/or residues from the substrate, wherein the plasma contains a ratio of active nitrogen and active oxygen that is larger than a ratio of active nitrogen and active oxygen obtainable from plasmas of gas mixtures comprising oxygen gas and nitrogen gas. The plasma exhibits high throughput while minimizing and/or preventing substrate oxidation and dopant bleaching. Plasma apparatuses are also described.

### BACKGROUND OF THE INVENTION

The present disclosure generally relates to front end of line (FEOL) plasma mediated ashing processes that provide effective removal of organic materials from a semiconductor substrate while enabling reduced substrate oxidation and/or erosion during processing, and more particularly, to plasma mediated ashing processes wherein the ratios of active nitrogen and active oxygen in the plasma is substantially larger than the ratio of active nitrogen and active oxygen obtained from plasmas of oxygen (O₂) and nitrogen (N₂) gas mixtures.

The integrated circuit manufacturing process can generally be divided into front end of line (FEOL) and back end of line (BEOL) processing. The FEOL processes are focused on fabrication of the different devices that make up the integrated circuit, whereas BEOL processes are focused on forming metal interconnects between the different devices of the integrated circuit. Examining the International Technology Roadmap for Semiconductors (ITRS) for FEOL processing reveals critical performance challenges faced by future devices in a number of key areas including plasma ashing. For example, the roadmap for plasma ashing projects target silicon loss for the 45 nanometer (nm) generation to being no greater than 0.4 angstroms per cleaning step and no greater than 0.3 angstroms for the 32 nm generation.

Typically, sensitive substrate materials such as silicon implanted with very shallow dopants, SiGe, high-k dielectrics, metal gates, and the like are exposed during the photoresist removal process and substrate damage can occur. The substrate damage may generally be in the form of substrate erosion (e.g., physical removal of a portion of the substrate caused by etching, sputtering, and the like), substrate oxidation, dopant bleaching/concentration changes, or combinations thereof These changes are undesirable as they will change the electrical, chemical, and physical properties of the substrate layer. Moreover, small deviations in the patterned profiles formed in the underlayers can adversely impact device performance, yield, and reliability of the final integrated circuit. For example, in a source and drain implant application, a patterned photoresist layer is formed over the silicon substrate at the source and drain regions prior to carrying out a high dose implant. During the high dose implant, the photoresist is subjected to relatively high energy ions that induce cross-linking reactions at a depth approximately equal to or slightly greater than the range of the ions in the photoresist. This cross-linking reaction and the resultant loss of hydrogen creates a hardened upper portion of the photoresist layer, commonly referred to as the crust. The physical and chemical properties of the crust vary depending on the implant conditions and are generally more resistant to plasma mediated ashing. Because of this, more aggressive plasma chemistries are needed to remove the resist. At the same time, however, extremely shallow junction depths call for very high selectivity in the resist removal process. Silicon loss or silicon oxidation from the source/drain regions must be avoided during the high-dose ion implantation strip. For example, excessive silicon loss can deleteriously alter electrical current saturation at a given applied voltage as well as result in parasitic leakage due to decreased junction depth detrimentally altering electrical functioning of the device. Current plasma mediated ashing processes are generally unsuitable for this type of application.

Traditional FEOL plasma mediated stripping processes are typically oxygen (O₂) based followed by a wet clean step. However, oxygen based plasma processes can result in significant amounts of substrate surface oxidation, typically on the order of about 10 angstroms or more. Because silicon loss is generally known to be governed by silicon surface oxidation for plasma resist stripping processes, the use of oxygen (O₂) based plasma ashing processes is considered by many to be unacceptable for the 32 and beyond technology nodes for advanced logic devices, where almost “zero” substrate loss is required and new materials are being introduced such as embedded SiGe source/drain, high-k gate dielectrics, metal gates and NiSi contact which are extremely sensitive to surface oxidation. Likewise, it has been found that traditional fluorine containing plasma processes, in addition to unacceptable substrate loss, results in dopant bleaching. Other FEOL plasma ashing processes use reducing chemistries such as forming gas (N₂/H₂), which provides good results as it relates to substrate oxidation but has throughput issues because of its lower resist removal rates. Moreover, hydrogen plasmas have been found to induce changes to the dopant distribution, which deleteriously affects the electrical properties of the device.

Because of this, prior plasma mediated ashing processes are generally considered unsuitable for removing photoresist in the FEOL process flow for the advanced design rules. Consequently, much attention has been directed to wet chemical removal of photoresist because of what is perceived as insurmountable problems associated with plasma mediated ashing for these design rules, e.g., substrate loss, dopant bleaching, and the like. As will be demonstrated herein, Applicant's have discovered viable plasma mediated stripping processes suitable for the advanced design rules that provide minimal substrate loss, dopant bleaching, and the like.

It is important to note that ashing processes significantly differ from etching processes. Although both processes may be plasma mediated, an etching process is markedly different in that the plasma chemistry is chosen to permanently transfer an image into the substrate by removing portions of the substrate surface through openings in a photoresist mask. The etching plasma generally exposes the substrate to high-energy ion bombardment at low temperatures and low pressures (of the order of millitorr) to physically remove selected portions of the substrate. Moreover, the selected portions of the substrate exposed to the ions are generally removed at a rate greater than the removal rate of the photoresist mask. In contrast, ashing processes generally refer to removing the photoresist mask and any polymers or residues formed during etching. The ashing plasma chemistry is much less aggressive than etching chemistries and is generally chosen to remove the photoresist mask layer at a rate much greater than the removal rate of the underlying substrate. Moreover, most ashing processes heat the substrate to further increase the plasma reactivity and wafer throughput, and are performed at relatively higher pressures (on the order of a torr). Thus, etching and ashing processes are directed to removal of photoresist and polymer materials for very different purposes and as such, require completely different plasma chemistries and processes. Successful ashing processes are not used to permanently transfer an image into the substrate. Rather, successful ashing processes are defined by the photoresist, polymer, and/or residue removal rates without affecting or removing underlying layers, e.g., the substrate, low k dielectric materials, and the like.

Based on the foregoing, what is needed in the art is a viable solution for photoresist removal as is needed for the advanced designed rules.

### BRIEF SUMMARY OF THE INVENTION

Disclosed herein are processes and apparatuses configured to provide a ratio of active nitrogen and active oxygen in a plasma that is substantially larger than the ratio of active nitrogen and active oxygen obtained from plasmas of oxygen (O₂) and nitrogen (N₂) gas mixtures.

In one embodiment, a front end of line plasma ashing process for removing photoresist, polymers and/or residues from a substrate comprises placing a substrate including photoresist, polymers and/or residues into a reaction chamber; generating a plasma from a gas mixture containing oxygen and nitrogen elements, wherein said plasma has a ratio of active nitrogen to active oxygen that is larger than a ratio of active nitrogen to active oxygen obtainable from a plasma formed of an oxygen gas and nitrogen gas mixture; and exposing the substrate to the plasma to selectively remove the photoresist, polymers and/or residues from the substrate.

In another embodiment, the process comprises placing the substrate including photoresist, polymers and/or residues into a reaction chamber; generating a plasma; and exposing the substrate to the plasma to selectively remove photoresist, polymers and/or residues from the substrate, wherein the plasma contains a ratio of active nitrogen and active oxygen that is larger than a ratio of active nitrogen and active oxygen obtainable from a plasma formed from a gas mixture comprising oxygen gas and nitrogen gas.

A plasma apparatus for ashing photoresist, polymers, and/or residues from a substrate comprises a plasma generating component for generating a plasma, wherein the plasma is configured to contain a ratio of active nitrogen and active oxygen that is larger than a ratio of active nitrogen and active oxygen obtainable from a plasma formed from gas mixtures comprising oxygen gas and nitrogen gas; a process chamber in fluid communication with the plasma generating component, the process chamber housing a substrate; and a material intermediate the plasma and the substrate configured to remove active oxygen from the plasma prior to exposure of the substrate to the plasma.

In another embodiment, the plasma apparatus comprises a plasma generating component for generating a plasma; a process chamber housing a substrate in fluid communication with the plasma generating component; and a material intermediate the plasma and the substrate configured to enhance active nitrogen in the plasma.

In still another embodiment, the plasma apparatus comprises a gas delivery component comprising at least two independent gas sources, wherein the gas sources are in fluid communication with separate plasma generation regions; and a process chamber housing a substrate in fluid communication with the plasma generating regions, wherein the plasma generation regions are configured to mix the plasma formed in the separate plasma generation regions prior to exposing the substrate to the plasma.

In yet another embodiment, the plasma apparatus comprises a primary gas source configured to deliver a first gas to form a plasma; a secondary gas source configured to deliver a second gas to the plasma to enhance formation of active nitrogen such that the plasma has a ratio of active nitrogen and active oxygen that is larger than a ratio of active nitrogen and active oxygen obtainable from plasmas of oxygen gas and nitrogen gas.

In yet another embodiment, the plasma apparatus comprises a plasma generating component operating at powers and pressures sufficient to keep the electron temperature of the plasma at the wafer surface at or below about 5.0 electron volts.

These and other features and advantages of the embodiments of the invention will be more fully understood from the following detailed description of the invention taken together with the accompanying drawings. It is noted that the scope of the claims is defined by the recitations therein and not by the specific discussion of features and advantages set forth in the present description.

### BRIEF DESCRIPTION OF THE DRAWINGS

The following detailed description of the embodiments of the invention can be best understood when read in conjunction with the following figures, which are exemplary embodiments, in which:

FIG. 1 illustrates a bar chart showing the relative amounts of active nitrogen to active oxygen produced for a prior art plasma formed from oxygen gas (O₂) and nitrogen gas (N₂) compared to plasmas formed in accordance with the present invention, wherein the ratio of active nitrogen to active oxygen is substantially greater than that obtainable from the prior art plasma of oxygen and nitrogen gases.

FIG. 2 graphically illustrates normalized silicon oxide growth as a function of oxygen content in the gas mixture used to form the plasma, wherein the gas composition includes oxygen (O₂) and nitrogen (N₂) mixtures, and oxygen (O₂) and forming gas (H₂/N₂) mixtures.

FIG. 3 schematically illustrates an exemplary plasma apparatus configured enhance the ratio of active nitrogen to active oxygen is substantially greater than that obtainable from the prior art plasma of oxygen and nitrogen gases

FIG. 4 illustrates a bar chart showing silicon oxide growth and photoresist ashing rates for a nitrous oxide based plasma (N₂O) compared to prior art plasma formed from a gas mixture of oxygen (O₂) and forming gas (N₂/H₂); and another prior art plasma formed from forming gas (N₂/H₂).

FIGS. 5A-C illustrate a bar chart showing substrate damage for a nitrous oxide-based plasma compared to prior art oxygen-based (O₂) plasmas and scanning electron micrograph images of a post p-MOS high-dose ion implant cleaning application. The substrate damage included (i) silicon loss from silicon-on-insulator (SOI) test structures, (ii) silicon-oxide growth on bare silicon test wafers and (iii) silicon-oxide loss from silicon thermal oxide test wafers. The SEM images in FIGS. 5B and 5C pictorially illustrate top down images after plasma strip followed by de-ionized water rinse for a plasma formed from O₂ and N₂/H₂ gas mixture (b) and a plasma formed from nitrous oxide gas (c).

FIG. 6 illustrates a bar chart showing silicon substrate loss, dopant loss, and photoresist ashing rate as a function of the plasma chemistry for nitrous oxide-based plasmas, forming gas based-plasma, oxygen and forming gas-based plasmas and a H₂/N₂ plasma with high hydrogen content.

FIG. 7 graphically illustrates silicon oxidation as a function of resist removed for nitrous oxide-based plasmas, and an oxygen and forming gas plasma. The graph exemplifies nitrous oxide plasma conditions with and without an active nitrogen enrichment configuration and with an optimized nitrous oxide strip plasma condition.

FIG. 8 graphically illustrates a bar chart showing the relative amounts of active oxygen and active nitrogen and the corresponding ratio of active oxygen and active nitrogen for the nitrous oxides plasmas of FIG. 7 that were obtained with and without the active nitrogen enrichment configuration.

FIG. 9 graphically illustrates wavelength as a function of intensity for a nitrous oxide based-plasma compared to plasma formed from an oxygen gas and a forming gas.

FIG. 10 graphically illustrates relative amounts of active nitrogen and active oxygen and the corresponding ratio of active nitrogen to active oxygen for nitrous oxide based plasmas at different power settings. Also shown is the corresponding silicon oxide growth for these plasmas.

FIG. 11 graphically illustrates relative amounts of active nitrogen and active oxygen and the corresponding ratio of active nitrogen to active oxygen for nitrous oxide based plasma, nitrous oxide based plasma with CF₄ additive, a plasma formed from O₂ gas and forming gas and a plasma formed from O₂ gas and N₂ gas.

FIG. 12 graphically illustrates the amount of silicon oxidation as a function of the electron temperature for an oxidizing plasma.

Skilled artisans will appreciate that elements in the figures are illustrated for simplicity and clarity and have not necessarily been drawn to scale.

### DETAILED DESCRIPTION OF THE INVENTION

Disclosed herein are plasma mediated ashing processes and apparatuses for selectively removing photoresist, ion implanted photoresist, polymers, residues, and/or like organic matter from a substrate. As will be described herein, the plasma mediated ashing processes and apparatuses provide a relatively high ashing rate, minimal or no substrate loss, minimal or no damage to underlying materials (e.g., high k dielectric materials), and minimal or no changes to a dopant distribution, among other advantages. As a result, the plasma mediated photoresist ashing processes and apparatuses described herein are suitable for FEOL processing for the 32 nm and beyond technology nodes where substrate loss must be kept to a minimum (less than 0.3 angstroms) and the electrical properties need to be substantially unchanged by the photoresist removal process.

The plasma mediated ashing processes generally include increasing the ratios of active nitrogen to active oxygen in the plasma such that the ratios are substantially larger from the active nitrogen to active oxygen ratio that is generally obtainable from plasmas of oxygen (O₂) and nitrogen (N₂) gas mixtures. As used herein, the terms active nitrogen and active oxygen generally refer to atomic or molecular, energetically excited, but electrically neutral nitrogen and oxygen species. FIG. 1 conceptually illustrates the differences in the obtainable ratio of active nitrogen and active oxygen based on plasmas formed from oxygen (O₂) and nitrogen (N₂) gases and contrasts these ratios with those obtainable by practicing Applicants' invention. As shown at the left side of the graph, prior art plasmas formed from mixtures of oxygen gas and nitrogen gas exhibit a ratio of active nitrogen to active oxygen that includes a relatively higher amount of active oxygen than active nitrogen, which Applicants have discovered is regardless of the particular oxygen and nitrogen gas composition utilized to form the plasma. In contrast, Applicants have discovered various means for increasing the ratio of active nitrogen to active oxygen in the plasma, which is substantially larger than that obtainable from plasmas formed from gas mixtures containing oxygen gas and nitrogen gas.

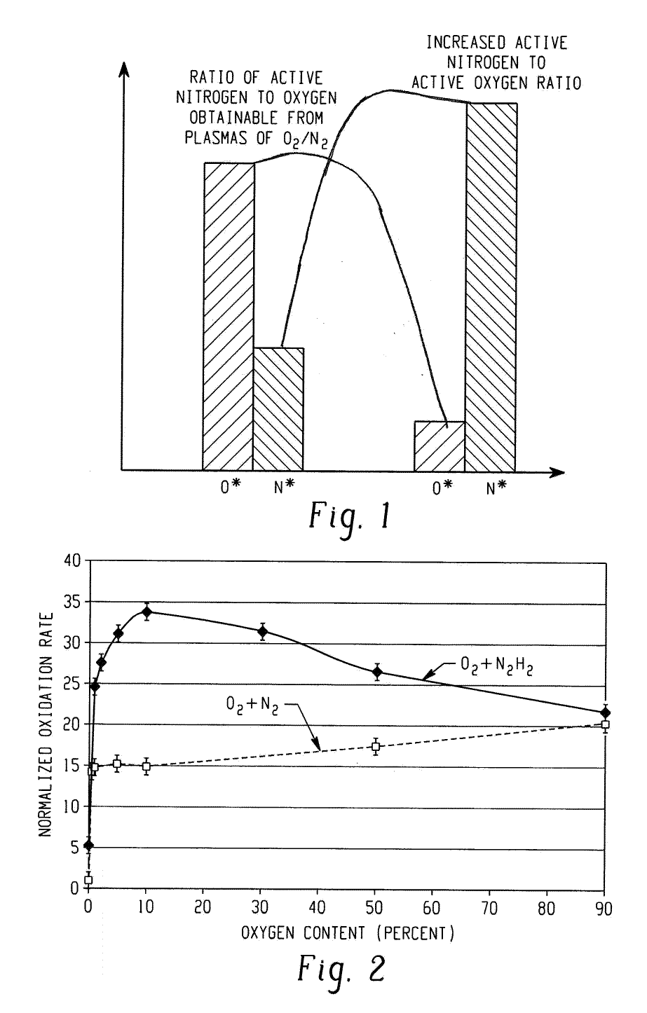

Referring to FIG. 2, there is graphically shown oxide growth as a function of oxygen gas (O₂) content in prior art gas mixtures that include both oxygen (O₂) and nitrogen (N₂) gases for forming the plasma. The evaluated gas mixtures included a mixture containing oxygen gas and nitrogen gas as well as one containing oxygen gas and forming gas, wherein the forming gas contained 3% hydrogen in nitrogen gas. As shown, the impact of oxygen even at trace amounts provided a deleterious effect on substrate oxidation. The smallest “non-zero” surface modification was observed at 0% oxygen. With regard to the two gas mixtures, a higher oxidation rate was observed for the plasma formed that included forming gas indicating that the active hydrogen species formed within the plasma significantly enhanced silicon oxidation. By changing the active nitrogen to active oxygen ratio, Applicants have unexpectedly discovered a means in which surface oxidization can be minimized. For comparative purposes, plasma formed from a gas containing both nitrogen and oxygen elements, e.g., nitrous oxide, exhibited less than about 4 Angstroms of oxide growth as a function of oxygen content under similar conditions.

As will be discussed in greater detail herein, the various means for increasing the ratio of active nitrogen to active oxygen in the plasma include the use of filters, gettering agents, and the like to remove and/or absorb the active oxygen species generated in the plasma upon excitation of O₂, thereby altering the ratio of active nitrogen to active oxygen by decreasing the amount of active oxygen within the plasma. Other means include increasing the amount of active nitrogen such as by forming the plasma from a gas mixture that includes the addition of a gas containing both nitrogen and oxygen elements. By way of example, generating plasma from a nitrous oxide (N₂O) gas or gas mixture containing the same has been found to provide a substantial increase in the amount of active nitrogen relative to the amount of active oxygen in the plasma, thus providing a substantial increase in the ratio of active nitrogen to active oxygen relative to the ratios obtainable from plasmas formed from oxygen (O₂) and nitrogen (N₂) gases. The use of catalysts, gas additives, decreases in operating pressure during plasma processing, lower power settings, different materials within the plasma chamber (e.g., upper baffle plates formed of quartz as opposed to sapphire), and the like can also be used, individually or in combination, to increase the ratio of active nitrogen to active oxygen such that it is substantially larger than that obtainable from plasmas formed from gas mixtures containing oxygen gas and nitrogen gas.

In one embodiment, the plasma mediated ashing process generally includes generating reactive species comprising active nitrogen and active oxygen from a gas mixture and exposing a substrate to the reactive species. The particular components of the plasma gas mixture generally depend on the particular embodiment employed for changing the active nitrogen to active oxygen ratio. For example, the plasma can be generated from gaseous nitrous oxide by itself or a mixture of the nitrous oxide gas with fluorine bearing gases, an oxidizing gas, an inert gas, a reducing gas, and various combinations thereof. In addition, the nitrous oxide gas or nitrous oxide gas mixture may further include various additives to increase photoresist removal rates and/or to minimize damage to the underlying materials, e.g., dielectric materials, substrate, metals, dopant concentration, and the like. It should be noted that although nitrous oxide is specifically referenced above as being suitable for increasing the ratio of active nitrogen to active oxygen in a plasma relative to one obtained using oxygen (O₂) and nitrogen (N₂) gases, other gases are contemplated that include both oxygen and nitrogen elements, e.g. nitric oxide, nitrogen trioxide, and the like.

Still further, the mixture can be formed from two or more plasmas that are combined in the process chamber. For example, plasma formed from an oxygen containing gas can be mixed with a plasma formed of a nitrogen containing gas. In this manner, one of the plasmas can be formed from oxygen gas (O₂) and the other plasma can be formed from a nitrogen containing gas that provides increased active nitrogen. Conversely, one of the plasmas can be formed from nitrogen gas (N₂) and the other plasma can be formed from an oxygen containing gas.

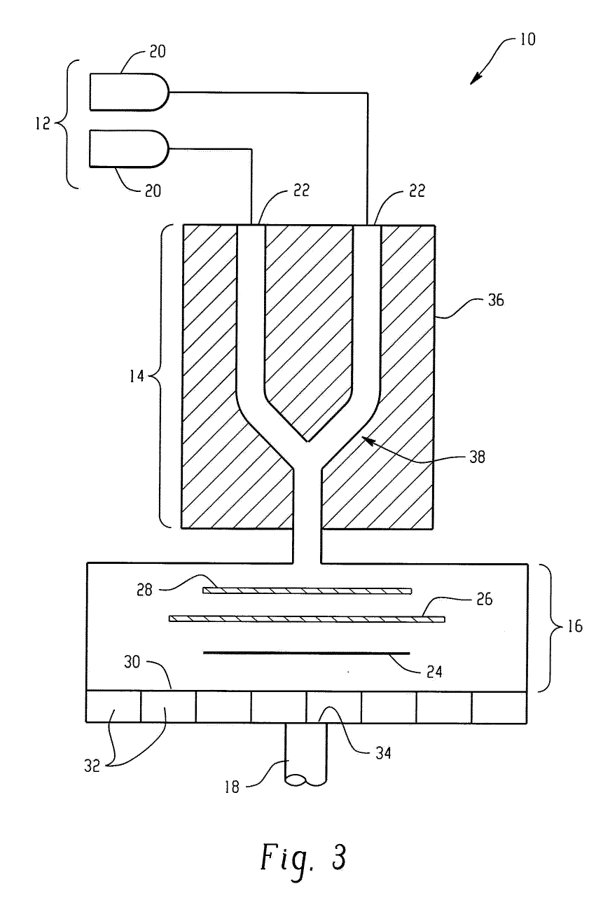

FIG. 3 illustrates an exemplary apparatus for generating multiple plasma streams generally designated by reference numeral 10. The plasma apparatus 10 generally includes a gas delivery component 12, a plasma generating component 14, a processing chamber 16, and an exhaust tube 18. The gas delivery component 12 may include a gas purifier (not shown) in fluid communication with one or more gas sources 20 that are in fluid communication with the plasma generating component. Using microwave excitation as an example of a suitable energy source for generating the plasma from a gas mixture, the plasma generating component 304 includes a microwave enclosure 36, which is generally a partitioned, rectangular box having the plasma tube 38 passing therethrough. As is known in the art, the microwave plasma generating component 14 is configured to cause excitation of the input gas into a plasma so as to produce a reactive species. In addition to microwave energy, the plasma generating component 304 could also be operated with an RF energy excitation source or the like. The plasma tube 38 includes a plurality of gas inlet openings 22, two of which are shown, into which the gases 20 from the gas delivery component 12 are fed. The plasma tube portions extending from the gas inlet openings are connected downstream from the plasma energy source. In this manner, different plasmas are generated within the apparatus, which are then mixed prior to exposing the substrate.

Once excited, the reactive species are introduced into an interior region of the processing chamber 16 for uniformly conveying the reactive species to the surface of a workpiece 24, such as a resist-coated semiconductor wafer. In this regard, one or more baffle plates 26, 28 are included within the processing chamber 16. Although the specific manner of operation of the baffle plates is not described in further detail hereinafter, additional information on such operation may be found in Ser. No. 10/249,964, referenced above. In order to enhance the reaction rate of the photoresist and/or post etch residue with the reactive species produced by the upstream plasma, the workpiece 24 may be heated by an array of heating elements (e.g., tungsten halogen lamps, not shown in the figures). A bottom plate 30 (transparent to infrared radiation) is disposed between the processing chamber 16 and the heating elements 32. An inlet 34 of the exhaust tube 18 is in fluid communication with an opening in the bottom plate for receiving exhaust gas into the exhaust tube 18.

Again, it should be understood that the plasma ashing apparatus 10 represents an example of one such device that could be used in conjunction with practicing the invention so as to generate different plasmas from different gas streams that are subsequently mixed prior to exposing the substrate to the plasma. Other suitable plasma apparatuses include medium pressure plasma system (MPP) operating at about 100 Torr so as to provide lower electron temperatures as well as single plasma tube configurations and those without baffles such as wide source area plasmas.

Suitable nitrogen containing gases where applicable for the different embodiments include, without limitation, N₂, N₂O, NO, N₂O₃, NH₃, NF₃, N₂F₄, C₂N₂, HCN, NOCl, ClCN, (CH₃)₂NH, (CH₃)NH₂, (CH₃)₃N, C₂H₅NH₂, mixtures, thereof, and the like.

Suitable inert gases for addition to the gas mixture include, without limitation, helium, argon, nitrogen, krypton, xenon, neon, and the like.

Suitable fluorine bearing gases include those gaseous compounds that generate fluorine reactive species when excited by the plasma. In one embodiment, the fluorine gaseous compound is a gas at plasma forming conditions and is selected from the group consisting of a compound having the general formula CₓH_{y}F_{z}, wherein x is an integer from 0 to 4 and y is an integer from 0 to 9 and z is an integer from 1 to 9 with the proviso that when x=0 then y and z are both are equal to 1, and when y is 0 then x is 1 to 4 and z is 1 to 9; or combinations thereof Alternatively, the fluorine bearing gas is F₂, SF₆, and mixtures thereof including, if desired, the fluorine bearing gases defined by the general formula CₓH_{y}F_{z} above.

The fluorine-bearing gases, when exposed to the plasma, are less than about 5 percent of the total volume of the plasma gas mixture to maximize selectivity. In other embodiments, the fluorine-bearing compounds, when exposed to the plasma, are less than about 3 percent of the total volume of the plasma gas mixture. In still other embodiments, the fluorine-bearing compounds, when exposed to the plasma, are less than about 1 percent of the total volume of the plasma gas mixture.

Suitable reducing gases include, without limitation, hydrogen bearing gases such as H₂, CH₄, NH₃, CxHy, wherein x is an integer from 1 to 3 and y is an integer from 1 to 6, and combinations thereof The hydrogen bearing compounds used are ones that generate sufficient atomic hydrogen species to increase removal selectivity of the polymers formed during etching and etch residues. Particularly preferred hydrogen bearing compounds are those that exist in a gaseous state and release hydrogen to form atomic hydrogen species such as free radical or hydrogen ions under plasma forming conditions. The hydrocarbon based hydrogen bearing compounds gas or may be partially substituted with a halogen such as bromine, chlorine, or fluorine, or with oxygen, nitrogen, hydroxyl and amine groups.

The hydrogen gas (H₂) is preferably in the form of a gas mixture. In one embodiment, the hydrogen gas mixtures are those gases that contain hydrogen gas and an inert gas. Examples of suitable inert gases include argon, nitrogen, neon, helium and the like. Especially preferred hydrogen gas mixtures are so-called forming gases that consist essentially of hydrogen gas and nitrogen gas. Particularly preferred is a forming gas wherein the hydrogen gas ranges in an amount from about 1 percent to about 5 percent by volume of the total forming gas composition. Although amounts greater than 5 percent can be utilized, safety becomes an issue due to risk of explosion of the hydrogen gas.

Suitable oxidizing gases include, without limitation, O₂, O₃, CO, CO₂, H₂O, and the like. When using oxidizing gases, it is generally preferred to remove any O* and O— species from the plasma prior to exposure to the substrate. It has been found that a causal factor of substrate oxidation is the reaction of the substrate with O* and O⁻ species. These species can easily diffuse through a growing SiOx surface oxide, thereby resulting in relatively thicker oxide growth. Additionally, the diffusion of these species can be enhanced by electric fields present or induced in the surface oxide. Because of this, a strategy for minimizing oxide growth should address both issues, namely: suppress O* and O— formation, and reduce or eliminate electric fields and oxide charging. As noted above, removal can be effected by increasing pressure within the reaction chamber during plasma processing, the addition of additives, addition of gases that contain both nitrogen and oxygen elements (.e.g., nitric oxide), and the use of filters, e.g., atomic and ionic filters.

The plasma mediated ashing process can be practiced in conventional plasma ashing systems. The invention is not intended to be limited to any particular hardware for plasma ashing. For example, a plasma asher employing an inductively coupled plasma reactor could be used or a downstream plasma asher could be used, e.g., microwave driven, Rf driven, and the like. The settings and optimization for particular plasma ashers will be well within the skill of those in the art in view of this disclosure. Plasma ashers generally are comprised of a plasma generating chamber and a plasma reaction chamber. For exemplary purposes only, in a 300 mm RpS320 downstream microwave plasma asher available from Axcelis Technologies, Inc., the present assignee, the substrates are heated in the reaction chamber to a temperature between room temperature and 450° C. The temperatures used during processing may be constant or alternatively, ramped or stepped during processing. Increasing the temperature is recognized by those skilled in the art as a method to increase the ashing rate. The pressure within the reaction chamber is preferably reduced to about 0.1 torr or higher. More preferably, the pressure is operated in a range from about 0.5 torr to about 4 torr. In some applications such as where gas phase recombination of undesired oxygen species (e.g., O*, O—) is desired so as to increase the ratio of active nitrogen to active oxygen in the plasma, higher operating pressures greater than 4 torr can be utilized, with greater than 10 torr used in some embodiments. The power used to excite the gases and form the plasma energy source is preferably between about 1000 Watts (W) and about 5000 W. A lower power setting can be used to increase the ratio of active nitrogen to active oxygen in the plasma, which is applicable to other types of plasma ashing tools.

The gas mixture comprising oxygen and nitrogen is fed into the plasma-generating chamber via a gas inlet. The gases are then exposed to an energy source within the plasma-generating chamber, e.g., microwave energy, preferably between about 1000 Watts (W) and about 5000 W, to generate excited or energetic atoms from the gas mixture. The generated plasma is comprised of electrically neutral and charged particles and excited gas species formed from the gases used in the plasma gas mixture. In one embodiment, the charged particles are selectively removed prior to plasma reaching the wafer. The total gas flow rate is preferably from about 500 to 12,000 standard cubic centimeters per minute (sccm) for the 300 mm downstream plasma asher. The photoresist, ion implanted photoresist, polymers, residues, and like organic matter are selectively removed from the substrate by reaction with the excited or energetic atoms (i.e., active species) generated by the plasma. The reaction may be optically monitored for endpoint detection as is recognized by those in the art. Optionally, a rinsing step is performed after the plasma ashing process so as to remove the volatile compounds and/or rinse removable compounds formed during plasma processing. In one embodiment, the rinsing step employs deionized water but may also include hydrofluoric acid and the like. The rinsing step, if applied, can include a spin rinse for about 1 to 10 minutes followed by spin drying process.

By way of example, modifications to the plasma hardware configurations can be made to increase the active nitrogen to active oxygen ratio. In one embodiment, an atomic and/or ionic O₂ filter and/or catalyst material is disposed intermediate the substrate and the plasma source so as to decrease the amount of active oxygen in the plasma. This filter can be a catalytic filter and/material, a surface recombination filter, a gas-phase recombination filter or the like. By way of example, the filter can be a surface reactive metals or metallic alloys, ceramics, quartz or sapphire materials for which the reactive gas passes over prior to interacting with the wafer surface. The effectiveness of this filter can be enhanced by controlling the temperature of the reactive surface as well as the shape and surface roughness of the reactive surface. In another embodiment, plasma ashing tools utilizing a dual baffle plate are modified such that the upper baffle plate is formed of quartz as opposed to sapphire, which has also been found to increase the ratio of active nitrogen to active oxygen. A similar effect is observed by forming the plasma tube of quartz instead of sapphire. Suitable gettering agents that can be used to reduce the active oxygen content in the plasma include, without limitation: metals such as B, Mg, Al, Be, Ti, Cr, Fe, Mn, Ni, Rb, Ir, Pb, Sr, Ba, Cs, and the like, or intermetallic compounds such as PrNi₅, Nd₂Ni₁₇, and the like, or ceramics such as TiO₂, Ta₂O₅, ZrO₂, Al₂O₃, FeO and the like, or gaseous substances, such as CO, NO, hydrocarbons, fluorocarbons, and the like, or semiconductors such as Si, Ge, and the like, or organometallics. Suitable catalysts for the formation of active nitrogen include, without limitation, metals such as Fe, Co, Ni, Ru, Re, Pt, Mo, Pd and the like or ceramics such as MgAl₂O₄ and the like. Active nitrogen formation can also be promoted by employing gas additives such as He, Ar, Kr, Xe, or by elements of design of the plasma source, such as plasma source surface materials and temperature, or by method of operation of the plasma source, such as excitation frequency, power density, electron temperature, gas mix ratio, or there like.

In another embodiment, a downstream plasma asher that selectively removes charged particles prior to exposure of the reactive species to the substrate is utilized, such as for example, downstream microwave plasma ashers commercially available under the trade name RpS320 from the Axcelis Technologies, Inc. in Beverly, Mass. For FEOL processing, it is generally desirable to remove substantially all of the charged particles from the reactive species prior to exposing the substrate to the reactive species. In this manner, the substrate is not exposed to charged particles that may deleteriously affect the electrical properties of the substrate. The substrate is exposed to the electrically neutral reactive species to effect photoresist, polymer, and/or residue removal.

An additional/emerging requirement is the need to maintain compatibility of the plasma ashing process with high-k dielectrics and metal gate materials. To promote compatibility, the nitrous oxide gas mixture or any of the various means discussed above that can be used increase the active nitrogen to active oxygen ratio may include additives chosen to reduce damage to these materials while maintaining sufficient reactivity to remove the photoresist and implanted crust materials. Suitable chemistry additives include, without limitation, halogen containing materials such as CF₄, CHF₃, C₂F₆, HBr, Br, HCl, Cl₂, BCl₃, CH₃Cl, CH₂Cl₂, and the like. These halogen containing additives can be effectively used to enhance removal of the portion of the photoresist layer referred to as the crust of an ion implanted photoresist. In this manner, a multi-step plasma ashing process can be used to remove the crust followed by a less aggressive plasma chemistry so as to remove the underlying photoresist, polymers, and residues, which is optionally be followed by a passivation or residue removal plasma step. For example, to protect the gate electrode and/or gate dielectric during plasma ashing of an ion implanted photoresist, a first step could include forming plasma with a nitrous oxide gas mixture that includes a halogen containing additive to remove the photoresist crust, followed by a plasma ashing step that includes forming the plasma with gaseous nitrous oxide only, i.e., a much less aggressive plasma than one containing the halogen containing additive. It should be noted that one or more of the multiple plasma steps do not require that the plasma have a ratio of active nitrogen and active oxygen that is larger than a ratio of active nitrogen and active oxygen obtainable from plasmas of oxygen gas and nitrogen gas. In some embodiments, only one of the multiple steps includes generating the plasma with the desired higher active nitrogen to active oxygen ratio.

The plasma mediated ashing process can be used to effectively ash, i.e., remove, photoresist, ion implanted photoresist, polymers, and/or post etch residues from the semiconductor substrate with minimal substrate loss and minimal dopant bleaching, dopant profile changes, or dopant concentration changes, among other advantages. Advantageously, the nitrous oxide plasma ashing process can be optimized to have ashing selectivity greater than 10,000:1 over silicon.

Photoresists are generally organic photosensitive films used for transfer of images to an underlying substrate. The present invention is generally applicable to ashing those photoresists used in g-line, i-line, DUV, 193 nm, 157 nm, e-beam, EUV, immersion lithography applications or the like. This includes, but is not limited to, novolaks, polyvinylphenols, acrylates, acetals, polyimides, ketals, cyclic olefins or the like. Other photoresist formulations suitable for use in the present invention will be apparent to those skilled in the art in view of this disclosure. The photoresist may be positive acting or negative acting depending on the photoresist chemistries and developers chosen.

The substrate can essentially be any semiconductor substrate used in manufacturing integrated circuits. Suitable semiconductor substrates generally include or may contain silicon; strained silicon; silicon germanium substrates (e.g., SiGe); silicon on insulator; high k dielectric materials; metals such as W, Ti, TiN, TaN, and the like; GaAs; carbides, nitrides, oxides, and the like. Advantageously, the process is applicable to any device manufacture where loss of material from the semiconductor substrate such as over a doped region is not desirable.

The following examples are presented for illustrative purposes only, and are not intended to limit the scope of the invention.

### EXAMPLE 1

In this example, photoresist coated onto a silicon substrate was exposed to a nitrous oxide stripping chemistry in a RapidStrip320 plasma ashing tool commercially available from Axcelis Technologies, Inc. The photoresist was an i-line photoresist commercially available from Fuji Company under the tradename 10i and was deposited onto the silicon substrate at a thickness of 1.9 microns. The plasma chemistry was formed by flowing nitrous oxide gas at 7 standard liters per minute (slm) into the plasma ashing tool at a pressure of 1 Torr, a temperature of 240° C., and a power setting of 3500 Watts.

Ashing rate, cross wafer uniformity, and oxide growth of the nitrous oxide plasma stripping process was compared with oxygen-free reducing plasma (forming gas) and an oxygen based plasma. The reducing plasma was formed from a gas mixture of forming gas (3% hydrogen in nitrogen) at a flow rate of 7 slm into the plasma ashing tool at a pressure of 1 Torr, a temperature of 240° C. and a power setting of 3500 Watts. The oxygen based plasma was formed using 90% oxygen (O₂) and 10% forming gas (3% hydrogen in nitrogen) at 7 slm into the plasma ashing tool at a temperature of 240° C. and a power setting of 3500 Watts.

Ashing rate and non-uniformity was measured after exposure of the photoresist to the respective plasma for 8 or 15 seconds. Oxide growth was measured by exposing uncoated silicon substrates to the respective plasma for 300 seconds.

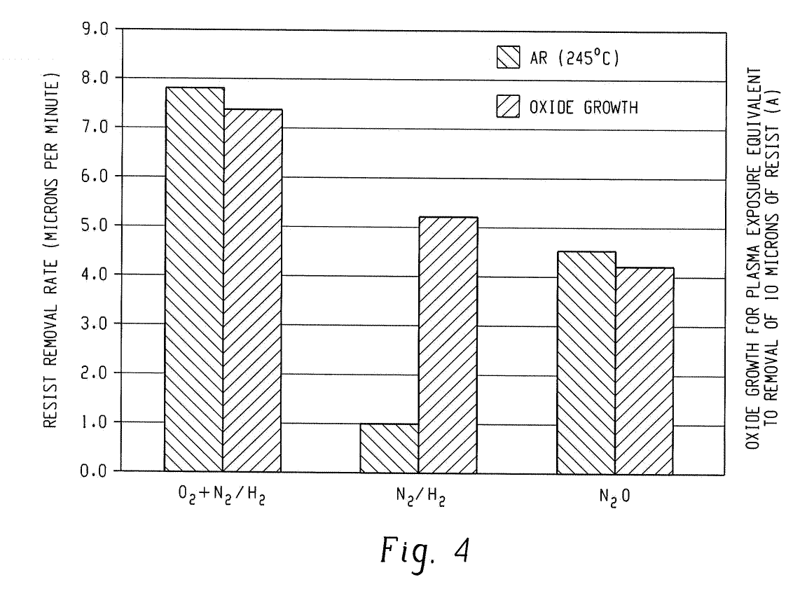

FIG. 4 illustrates the results. As expected, oxide growth for the oxygen based plasma was significant at about 12 angstroms (Å) and exhibited the highest ashing rate at about 7.8 μm/min. In contrast, the reducing plasma and the nitrous oxide plasma showed a significant improvement relative to the oxygen based plasma but had lower ashing rates. The nitrous oxide based plasma compared to the reducing plasma exhibited less oxide growth; about 3.0 Å for the nitrous oxide based plasma compared to ˜4 Å for the reducing plasma. Notably, the nitrous oxide based plasma exhibited an ashing rate of about 4 μm/min compared to about 1.0 μm/min for the reducing plasma. Also, ashing non-uniformity for the nitrous oxide based plasma (non-uniformity=2.8%) was significantly better than the forming gas (>10%) under the same processing conditions.

### EXAMPLE 2

In this example, a small amount of CF₄ was added to different plasma gas mixtures and processed in the RapidStrip320 plasma ashing tool. Silicon substrates were exposed to the different plasma chemistries and oxide growth was measured. The results are shown in Table 1 below. In each instance, the various plasmas were formed using a flow rate of the gas mixture of 7 slm into the plasma ashing tool at a pressure of 1 Torr, and a power setting of 3500 Watts. As indicated in the Table, the amount of CF₄ trickled into the plasma ashing tool, where indicated, was 20 standard cubic centimeters per minute (sccm).

TABLE 1

| Plasma Chemistry | Process Time | Oxide Growth (Å) |
|---|---|---|
| CF₄/N₂O | 103 | 3.24 |
| CF₄/3% O₂/Forming Gas | 103 | 9.54 |
| CF₄/90% O₂/Forming Gas | 103 | 8.76 |
| 3% O₂/Forming Gas | 140 | 9.82 |

As shown, trickling CF₄ during formation of the plasma resulted in minimal substrate loss as evidenced by the oxide growth, and advantageously, can be expected to produce more energetic species, which should effectively increase the ashing rate relative to the results observed in Example 1.

### EXAMPLE 3

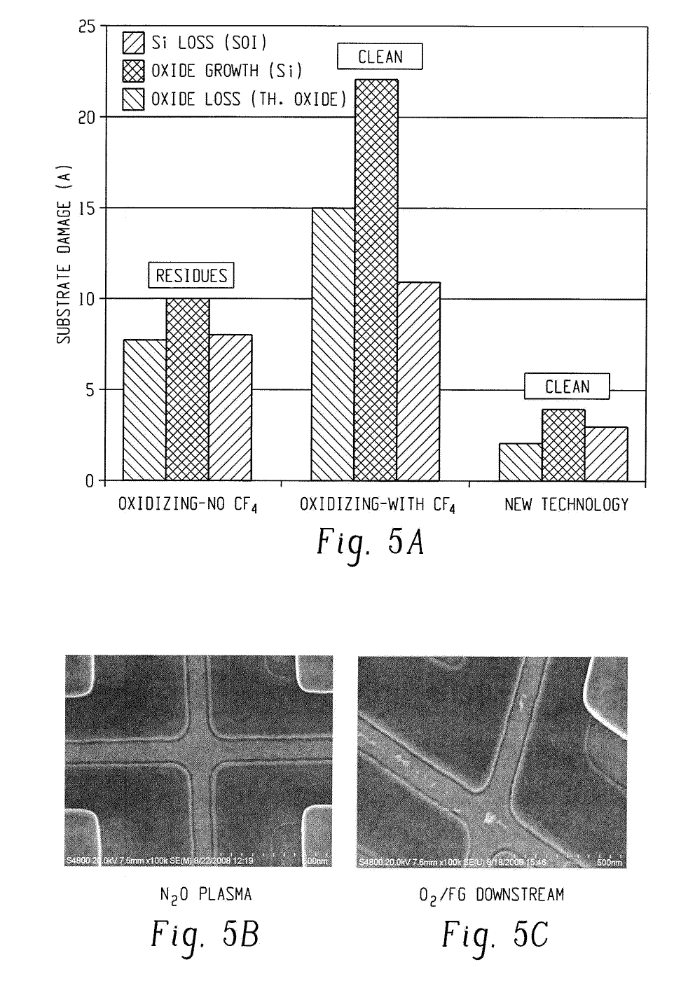

In this example, substrate damage was measured using the RapidStrip320 plasma ashing tool in terms of silicon loss, oxide growth and oxide loss for a plasma formed from nitrous oxide, which was compared to prior art plasmas formed from O₂/forming gas mixtures with and without a small amount of carbon tetrafluoride. The forming gas composition was 3% hydrogen in nitrogen. The results are graphically shown in FIG. 5A. In each instance, the various plasmas were formed using a flow rate of the gas mixture of 7 slm into the plasma ashing tool at a pressure of 1 Torr, a temperature of 240° C. and a power setting of 3500 Watts. The amount of CF₄ trickled into the plasma ashing tool, where indicated, was 20 standard cubic centimeters per minute (sccm). The substrate damage included (i) silicon loss from silicon-on-insulator (SOI) test structures, (ii) silicon-oxide growth on bare silicon test wafers and silicon-oxide loss from silicon thermal oxide test wafers. Panels (b) and (c) compare scanning electron micrograph images of a post p-MOS high-dose ion implant cleaning application. The SEM images are shown after plasma strip followed by de-ionized water rinse for a plasma formed from O₂ and N₂/H₂ gas mixture (c) and a plasma formed from nitrous oxide gas, indicating substantially improved residue removal capability of the plasma from the nitrous oxide gas mixture

The results clearly show a substantial decrease in substrate damage for the plasma having the relatively high active nitrogen to active oxygen ratio. Residues were observed from the oxidizing plasma without carbon tetrafluoride. Moreover, as noted in FIGS. 5B and 5C, residue removal was significantly improved using the nitrous oxide plasma.

### EXAMPLE 4

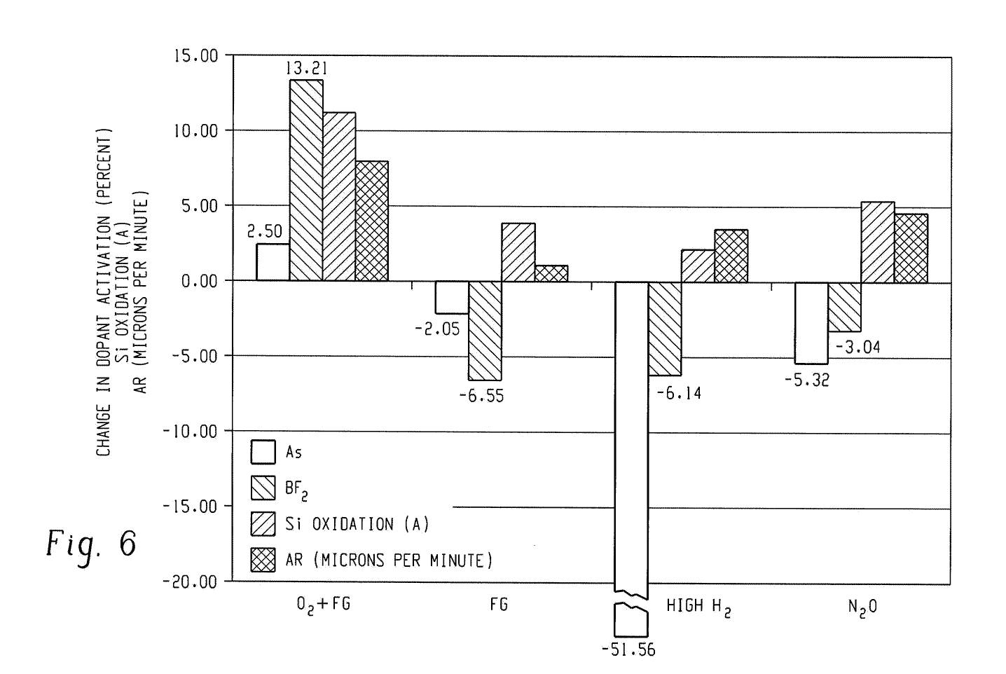

In this example, dopant loss, substrate loss and ashing rate were monitored during plasma processing using plasmas formed from nitrous oxide, forming gas (3% H₂, 97% N₂), oxygen gas (90%) and forming gas (10%), and forming gas with a high amount of hydrogen gas. (a mixture of 90% H₂ and 10% N2). All plasmas were formed with 7 slm of total gas flow and 3500 W of microwave power. The substrates were heated to a temperature of 240° C. during the plasma processing. The silicon oxidation process time was 5 minutes. The process time to determine resist removal was 8 seconds or 15 seconds. For the dopant profile tests, blanket silicon wafers were implanted with either As or BF₂ with an energy of 2 keV and a dose of 5.0 E14. The wafers were then exposed to the various ash plasmas for 5 minutes and annealed at 1050 C for 10 seconds. Secondary ion mass spectroscopy (SIMS) analysis was performed to determine the dopant profile, and sheet resistance (Rs) measurements were performed to determine the sheet resistance. The results are graphically shown in FIG. 6.

As shown, the plasma formed using the highest active nitrogen to active oxygen ratio exhibited robust behavior for both As and BF₂ implantation in addition to ashing rate and oxidation.

### EXAMPLE 5

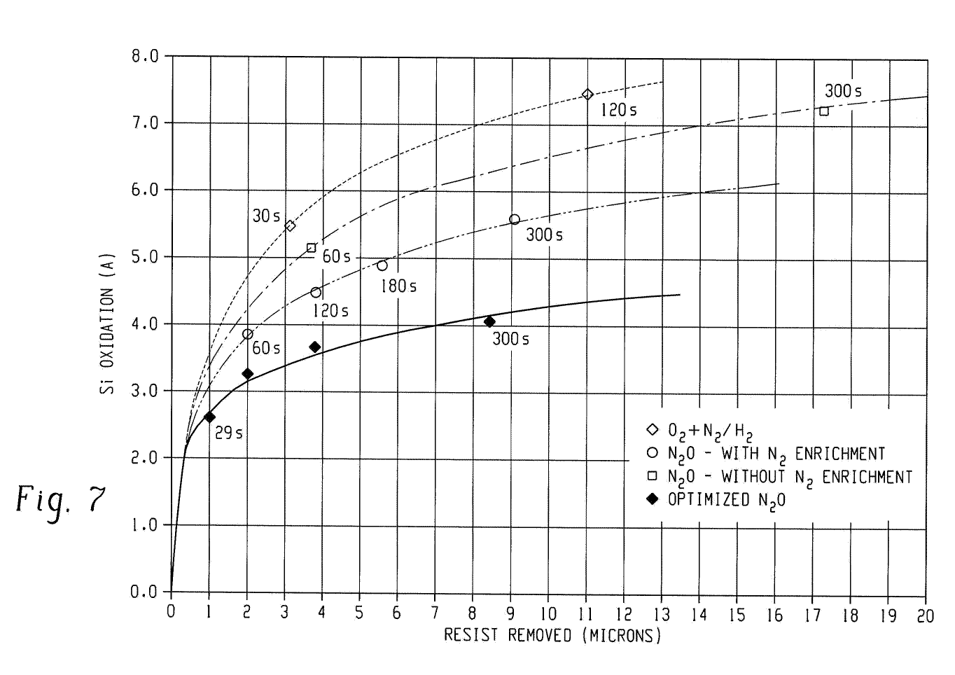

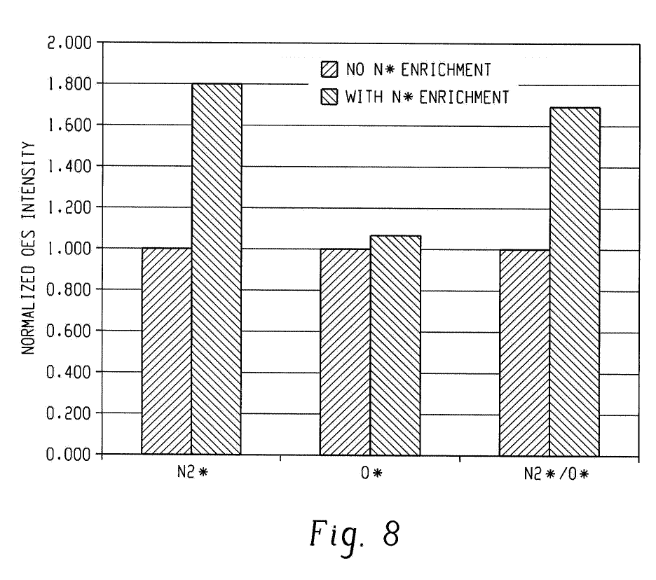

In this example, the effect of an active nitrogen enriching configuration is illustrated. Configuring the RPS320 plasma source with a sapphire tube (active nitrogen enriching configuration) did result in reduced silicon oxidation (FIG. 7) compared to the configuration with a quartz tube (non-nitrogen-enriching configuration). FIG. 8 shows that this exemplary nitrogen-enriching configuration (a sapphire plasma tube compared to a quartz plasma tube) does result in increased active nitrogen, while the amount of active oxygen remains substantially unchanged and the corresponding ratio of active nitrogen to active oxygen being increased. FIG. 7 furthermore illustrates an optimized configuration for the nitrous oxide plasma, comprised of optimized microwave power, temperature, and plasma tube composition, which is shown to substantially reduce the silicon oxidation.

As shown, relative to plasma formed from the standard oxygen and forming gas composition, all of the plasmas formed of nitrous oxide exhibited lower oxidation as a function of resist removed. In addition, lowering the temperature and power setting resulted in lower oxidation and an increased ashing rate. Moreover, the plasma formed from nitrous oxide exhibited much faster ashing rate compared to the control plasma of forming gas.

### EXAMPLE 6

In this example, optical emission spectroscopy was used to analyze the plasma formed from nitrous oxide relative to a standard plasma process formed from 90% oxygen gas and 10% forming gas (3% H₂/97% N₂). The plasmas from each gas were generated in the RPS320 with 3500 W and a total gas flow of 7 slm. The optical emission of the plasma was collected with an Ocean Optics optical emission spectrometer through a view port on the process chamber at wafer level.

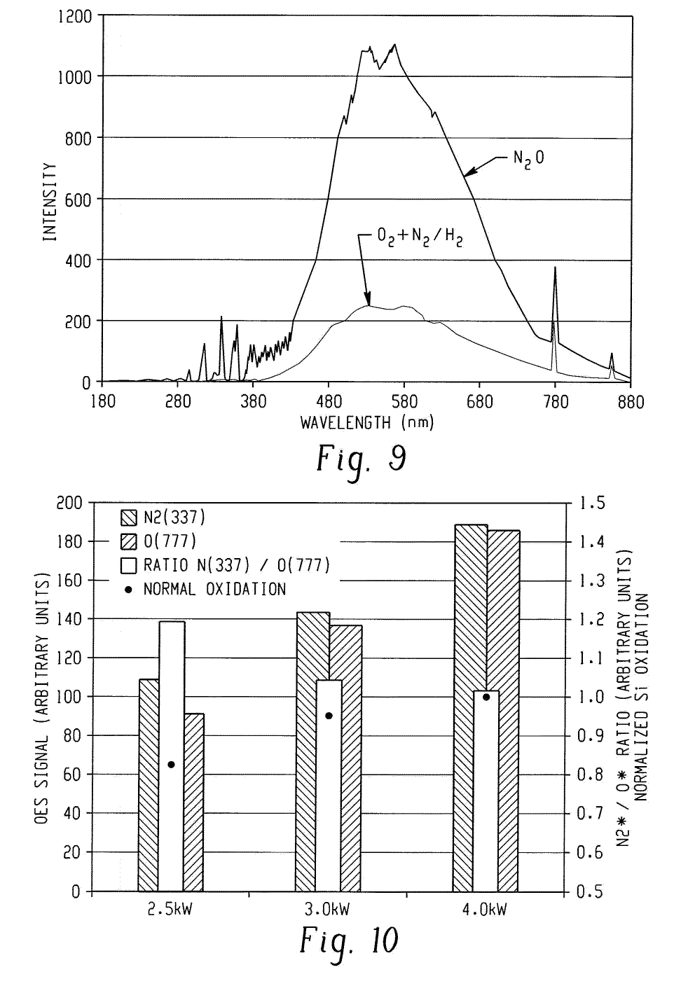

FIG. 9 graphically illustrates wavelength as a function of intensity. Noteworthy are the emission signals between about 300 and 380 nm that correspond to N2* active species that are generated in the plasma formed from nitrous oxide. In contrast, no discernible amounts of N2* were observed for the standard plasma process. As such, the ratio of active oxygen to active N2 (O*:N2*) is significantly higher in the standard plasma process than the nitrous oxide process. While not wanting to be bound by theory, the N2* is believed to contribute to the lower oxidation in the nitrous oxide process but also appears to contribute to a lower ashing rate as well. In addition to this observation, the figure graphically shows that the nitrous oxide based process produced significantly more NO.

### EXAMPLE 7

In this example, optical emission spectroscopy was used to measure the ratio of active nitrogen to active oxygen as a function of microwave plasma for plasmas formed from nitrous oxide. Using the RapidStrip320 plasma ashing tool, the plasma chemistry was formed by flowing nitrous oxide gas at 7 standard liters per minute (slm) into the plasma ashing tool at a pressure of 1.0 Torr, a temperature of 240° C. As shown in FIG. 10, the ratio increased as a function of lowering the microwave power, wherein a ratio of 1.2 was observed at the lowest evaluated setting of 2.5 kW. Also shown is the relative amount of silicon surface oxidation for the tested nitrous oxide plasma conditions, illustrating good correlation of the amount of silicon oxidation to the ration of active plasma nitrogen and active oxygen.

### EXAMPLE 8

In this example, optical emission spectroscopy was used to measure the ratio of active nitrogen to active oxygen for plasmas formed from (i) nitrous oxide gas, (ii) nitrous oxide gas with a CF₄ additive, (iii) a mixture of 90% oxygen gas and 10% forming gas (3% H₂/97% N₂), and (iv) a mixture of 90% oxygen gas and 10% nitrogen gas. For the purpose of illustration, the amounts of measured active oxygen and active nitrogen shown in FIG. 11 for the different plasmas were normalized to reflect a value of one for the O₂+N₂ plasma. The corresponding ratio of active nitrogen to active oxygen are substantially higher for the plasmas formed with the nitrous oxide gas mixtures and lower for the plasma formed from the gas mixture of O₂+FG gas mixture, which is well correlated with the earlier reported amounts of silicon oxidation. It is noteworthy to mention that the amounts of active oxygen are relatively similar for all four evaluated plasmas, and that there are significant differences in the amounts of active plasma nitrogen.

### EXAMPLE 9

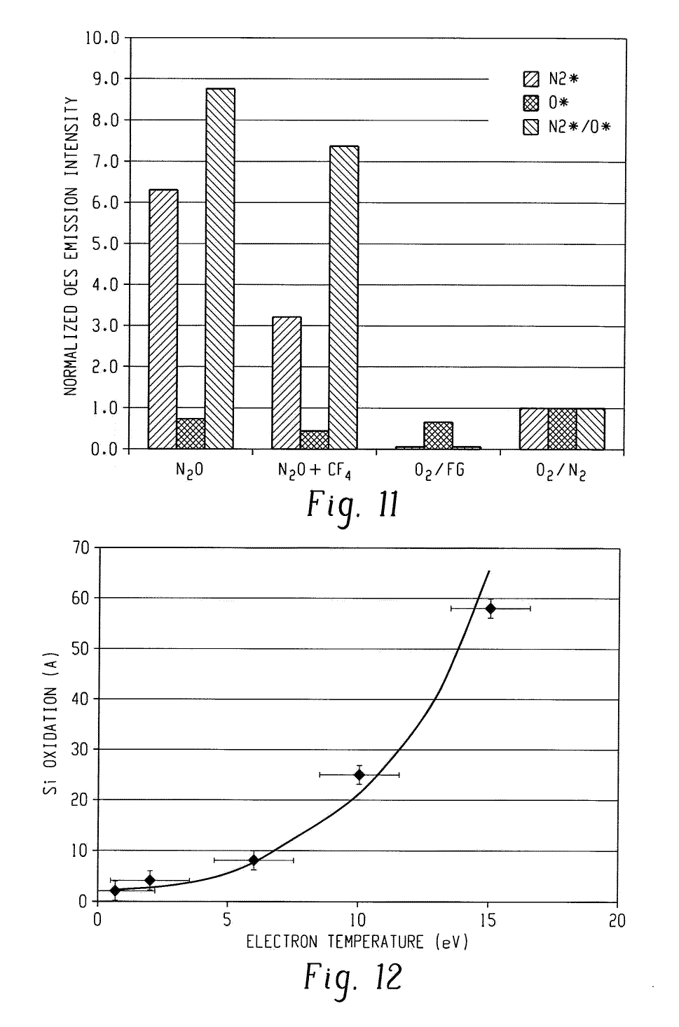

In this example, FIG. 12 graphically illustrates the amount of silicon oxidation as a function of the electron temperature for oxidizing plasma. Plasmas formed from 90% oxygen gas and 10% forming gas showed that silicon oxidation increases exponentially as the electron temperature of the plasma increases. Low silicon oxidation requires maintaining a low electron temperature below about 5.0 electron volts.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the embodiments of the invention belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

While embodiments of the invention have been described with reference to exemplary embodiments, it will be understood by those skilled in the art that various changes can be made and equivalents can be substituted for elements thereof without departing from the scope of the embodiments of the invention. In addition, many modifications can be made to adapt a particular situation or material to the teachings of embodiments of the invention without departing from the essential scope thereof. Therefore, it is intended that the embodiments of the invention not be limited to the particular embodiment disclosed as the best mode contemplated for carrying out this invention, but that the embodiments of the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A front end of line plasma ashing process for removing photoresist, implanted photoresist, polymers and/or residues from a substrate, the process comprising:
placing the substrate including photoresist, polymers and/or residues into a reaction chamber;
generating a plasma from a gas mixture containing oxygen and nitrogen elements, wherein said plasma has a ratio of active nitrogen to active oxygen that is larger than a ratio of active nitrogen to active oxygen obtainable from a plasma formed of an oxygen gas and nitrogen gas mixture; and
exposing the substrate to the plasma to selectively remove photoresist, polymers and/or residues from the substrate.

2. The front end of line ashing process of claim 1, wherein said at least one gas containing the oxygen and nitrogen elements comprises nitrous oxide.

3. The front end of line ashing process of claim 1, wherein said process includes exposing said gas mixture containing oxygen and nitrogen to a catalyst for enhancing formation of active nitrogen.

4. The front end of line ashing process of claim 1, wherein said process includes inputting a gas additive to said gas mixture containing oxygen and nitrogen for enhancing formation of active nitrogen.

5. The front end of line ashing process of claim 1, wherein said process comprises generating the plasma in a plasma tube formed of quartz.

6. The front end of line ashing process of claim 1, wherein said process includes passing said plasma through a filter for reducing the amount of active oxygen in said gas mixture.

7. The front end of line ashing process of claim 1, wherein said process includes exposing said plasma to a gettering agent for reducing the amount of active oxygen in said gas mixture.

8. The front end of line ashing process of claim 1, wherein said process includes decreasing a chamber pressure housing said plasma and the substrate for enhancing formation of active nitrogen.

9. The front end of line ashing process of claim 1, wherein said plasma generating step includes exposing said gas mixture containing oxygen and nitrogen to rf energy for generating said plasma.

10. The front end of line ashing process of claim 1, wherein said plasma generating step includes exposing said gas mixture containing oxygen and nitrogen to microwave energy for generating said plasma.

11. The front end of line ashing process of claim 1, wherein exposing the substrate to the plasma comprises removing substantially all of the charged particles from the reactive species prior to exposing the substrate.

12. The front end of line ashing process of claim 1, wherein the plasma has an electron at or below 5.0 electron volts.

13. The front end of line ashing process of claim 2, wherein the gas mixture further comprises CF₄.

14. A front end of line plasma ashing process for removing photoresist, polymers and/or residues from a substrate, the process comprising:
placing the substrate including photoresist, polymers and/or residues into a reaction chamber;
generating a plasma; and
exposing the substrate to the plasma to selectively remove photoresist, polymers and/or residues from the substrate, wherein the plasma contains a ratio of active nitrogen and active oxygen that is larger than a ratio of active nitrogen and active oxygen obtainable from a plasma formed from a gas mixture comprising oxygen gas and nitrogen gas.

15. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by exposing said plasma to a catalyst for enhancing formation of active nitrogen relative to active oxygen.

16. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by introducing a gas additive to a gas mixture for generating the plasma.

17. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by exposing the plasma to a filter so as to reduce the amount of active oxygen in the plasma prior to exposing the substrate.

18. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by exposing the plasma to a gettering agent to reduce the amount of active oxygen in the plasma prior to exposing the substrate.

19. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by decreasing a pressure in a reaction chamber adapted to house the plasma and the substrate, wherein the decrease in pressure is in an amount effective to enhance formation of active nitrogen relative to active oxygen.

20. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by contacting the plasma with a quartz baffle plate prior to exposing the substrate.

21. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by generating the plasma in a plasma tube formed of quartz.

22. The front end of line ashing process of claim 14, wherein the plasma containing the ratio of active nitrogen and active oxygen that is larger than the ratio of active nitrogen and active oxygen obtainable from plasmas of gas mixtures comprising oxygen gas and nitrogen gas is formed by generating the plasma with a gas mixture containing at least one gas containing both oxygen and nitrogen elements.

23. The front end of line ashing process of claim 14, wherein the plasma has an electron temperature at or below 5.0 electron volts.

24. The front end of line ashing process of claim 22, wherein the at least one gas containing both oxygen and nitrogen elements is nitrous oxide.

25. The front end of line ashing process of claim 22, wherein the gas mixture contains an oxygen containing gas and a nitrogen containing gas with the proviso that when the nitrogen containing gas is N₂ the oxygen containing gas is not O₂ and when the oxygen containing gas is O₂ then the nitrogen containing gas is not N₂.

26. A plasma apparatus for ashing photoresist, polymers, and/or residues from a substrate, the apparatus comprising:
a plasma generating component for generating a plasma, wherein the plasma is configured to contain a ratio of active nitrogen and active oxygen that is larger than a ratio of active nitrogen and active oxygen obtainable from a plasma formed from gas mixtures comprising oxygen gas and nitrogen gas;
a process chamber in fluid communication with the plasma generating component, said process chamber housing the substrate; and
a material intermediate the plasma and the substrate configured to remove active oxygen from the plasma prior to exposure of the substrate to the plasma.

27. The plasma apparatus of claim 26, wherein the material is a gettering agent.

28. The plasma apparatus of claim 26, wherein the material is a filter selected from a group consisting of a surface recombination filter, a catalytic filter and a gas-phase recombination filter.

29. The plasma apparatus of claim 26, wherein the filter comprises an aluminum oxide ceramic or sapphire material.

30. A plasma apparatus for ashing photoresist, polymers, and/or residues from a substrate, the apparatus comprising:
a plasma generating component for generating a plasma;
a process chamber housing a substrate, said process chamber in fluid communication with the plasma generating component; and
a material intermediate the plasma and the substrate configured to enhance active nitrogen in the plasma.

31. The plasma apparatus of claim 30, wherein the material is a catalyst.

32. The front end of line ashing process of claim 30, wherein the plasma has an electron temperature at or below 5.0 electron volts.

33. A plasma apparatus for ashing photoresist, polymers, and/or residues from a substrate, the apparatus comprising:
a gas delivery component comprising at least two independent gas sources, the gas sources in fluid communication with separate plasma generation regions;
a process chamber housing a substrate in fluid communication with the plasma generating regions, wherein the plasma generation regions are configured to mix the plasmas formed in the separate plasma generation regions prior to exposing the substrate to the mixed plasma.

34. The plasma apparatus of claim 33, wherein the at least two independent gas sources comprise a gas source for providing nitrogen containing gas and a gas source for providing oxygen containing gas.

35. The front end of line ashing process of claim 33, wherein the plasma has an electron temperature at or below 5.0 electron volts.

36. A plasma apparatus for ashing photoresist, polymers, and/or residues from a substrate, the apparatus comprising:
a primary gas source configured to deliver a first gas to form a plasma;
a secondary gas source configured to deliver a second gas to the plasma to enhance formation of active nitrogen such that the plasma has a ratio of active nitrogen and active oxygen that is larger than a ratio of active nitrogen and active oxygen obtainable from a plasma of oxygen gas and nitrogen gas.

37. The front end of line ashing process of claim 36, wherein the plasma has an electron temperature at or below 5.0 electron volts.
